(19) United States
(12) Patent Application Publication
(10) Pub. No.: US 2010/0199212 A1
(43) Pub. Date: Aug. 5, 2010

(54) Operating Element For Display-Supported Technical Systems

(75) Inventors: Rainer Heers, Koeln (DE); Thomas Sulzbach, Koeln (DE)

Correspondence Address: DICKINSON WRIGHT PLLC, 1875 Eye Street, NW, Suite 1200, WASHINGTON, DC, 20006, US

(73) Assignee: VISTEON GLOBAL TECHNOLOGIES, INC., Van Buren Township, MI (US)

(21) Appl. No.: 12/558,668

(22) Filed: Sep. 14, 2009

(30) Foreign Application Priority Data
Sep. 26, 2008 (DE) 102008049122.5-34

(51) Int. Cl. G06F 3/048; H03K 17/94

(52) U.S. Cl. 715/784; 715/856; 715/810; 341/34

(57) ABSTRACT

The invention relates to an operating element for technical systems in vehicles, comprising four separately operable key elements (8, 9, 10, 11) and a turnably supported roller (2), which can be moved by compression perpendicular to its axis of rotation (18), whereby the four key elements (8, 9, 10, 11) are placed crosswise and the turnably supported roller (2) is in the middle between the crosswise-placed key elements (8, 9, 10, 11), whereby the axis of rotation (18) runs parallel to the plane of the key elements (8, 9, 10, 11), and the movability of the roller (2) is perpendicular to this plane.

### CROSS REFERENCE TO RELATED APPLICATION

This application claims the benefit of German Patent Application No. 10 2008 049 122.5-34 filed Sep. 26, 2008, entitled “Operating Element For Display-Supported Technical Systems,” the entire disclosure of this application being incorporated by reference.

### BACKGROUND OF THE INVENTION

1. Technical Field

The invention relates generally to an operating element for technical systems, in particular an operating element for display-supported technical systems that are used in vehicles. Multiple requirements are made for such operating elements, of which the most important are sketched beforehand briefly.

2. Discussion

One particular feature of using technical systems in moving vehicles is that operation of the system frequently occurs while the vehicle is moving and the requisite operating elements and the operator, typically the driver of the vehicle, is subject to varied movements and accelerations in various directions, some not foreseeable. These movements and accelerations can, for example, appear while crossing or traveling uneven road sections. Regardless of that, incorrect operations are desirable to be precluded as much as possible. In addition, the operating element should be capable of being operated with minimal impairment in visibility when the operator is actively engaged in driving. Operability must nevertheless be balanced with notions of comfort that potential customers connect with the particular vehicle.

Many automobile manufactures strive to employ brand-specific operating and display concepts into the vehicle's cockpit, to give specific support to brand identity through a suitable configuration of the vehicle's passenger compartment. General features for a successful and positive operation by the operator and pleasing display concepts are operational simplicity and/or the attractiveness of the operating experience, as can be attained through appropriately configured operating elements and easily and intuitively configured user guidance.

One problem in specifically working out an operating element and display concept, for example of an operational and display concept for a vehicle cockpit, is that ergonomic and software-ergonomic considerations play a particular role, especially in designing possible safe operations of complex systems while driving. Certain of these considerations are reflected, among other things, in a comprehensive set of regulations and corresponding standards, such as ISO DIN 15008, ISO DIN 17287, ISO DIS 26022, as well as the European Statement of Principles (EsoP) ergonomic guidelines of the European Union, the “AAM Guideline” by the Association of Automobile Manufacturers in the U.S.A.; and the “JAMA Guideline” of the Japanese Automobile Manufacturers Association. Therefore, operating elements possibly used in these surroundings must comply with the above regulations and corresponding standards.

In addition to the above considerations including the above regulations and standards, customary display and operational concepts in vehicles have markedly changed overall in recent years and continually change. Initially in high-end vehicles, but also increasingly in vehicles of the upper, middle and compact classes, ever more complicated operating systems are increasingly used. These systems provide access to functions of varied technical systems installed in vehicles, such as radio and audio systems, navigation systems, air conditioners, driver information and assistance systems. In addition, vehicles are including a greater number of controllable functions and increasingly more complex operating options, such as options that may relate to vehicle adjustments. Other options or functions commonly found in vehicles are systems that may display and/or control functions of mobile end devices like mobile telephones, portable navigation devices, PDAs and also notebooks and laptops. These mobile devices increasingly are being included at least temporarily into the cockpit architecture or configured to interface with the system and in this case are to be assumed into the corresponding operating concept while using unitary operating elements.

Many manufacturers and designers have strived to create safe, comfortable and to the maximum extent, possible malfunction-free operation of the technical systems covered, and while various operating concepts have been established, so far, none of them fully meet the above named requirements.

Many systems use a large formal screen, especially systems with numerous functions. Generally, the large format screen is located in the center console, and in many vehicles the operating elements are generally not located in the immediate vicinity of the screen. When the operating elements are located away from the display screen, these concepts are generally designated as remote operating concepts. Such systems with remote concepts represent a form of display-supported technical systems in accordance with the following explanations. These systems predominantly use multifunctional, multi-path rotated or pressed devices.

Operating tasks that fundamentally appear in display-supported systems amount typically to navigation between differing display elements for dialing up individual display elements and/or selection actions regarding depicted or selected display elements. In doing so the selection actions lead either to display of further display elements, for example by opening submenus, or to activation of technical functions that are connected with the display element in question.

Customary and traditional operating elements in vehicles, especially mechanical and electromechanical ones, like switches, rotating knobs, toggle switches, turning adjusters, lockdown adjusters or similar additional to multiple-function operating elements are used with systems or combined in various ways to implement the required navigation or selection actions on the display for display-supported systems.

Thus, it is known in such concepts to use 4- or 8-path lockdown adjusters as fully adjusted solutions in so-called I-drive systems of BMW or COMAND systems of Mercedes. However, it is also known to use other combinations of lockdown adjusters with operating elements such as Audi's MMI concept, or in the U.S. version of the Honda Acura RL or in the Honda Legend, the European version of the Acura RL.

In certain situations, the listed operating concepts do not allow a simultaneous optimal and integrated operation and display of functions and applications that is at the same time optimally adapted to the particular conditions of operation of technical display-supported systems while driving.

The ergonomic advantage of the listed multi-function lockdown adjuster lies in the possibility to optimize the position of the operating element thus designed within the easy reach of the driver, for example in front of the arm rest in the center console. However, due to its round shape and multi-functionality, this ergonomic advantage may be distracting and not intuitive to operate, particularly when also operating the vehicles. A decisive disadvantage of such systems becomes obvious when it is a question of an intuitive operation, which must distract the driver as little as possible. Especially since no unambiguous or exclusive assignment exists of the particular turning motion of the input device of the motion caused thereby on the screen, which must occur between vertically or horizontally assigned display elements during a desired dial-up, during operation often a great degree of attention is required of the operator. Thus with the turning motion, for example horizontal motions are carried out on a marking element between display elements, as these for example are required with selection of menu entries in a horizontally organized menu or selection of a radio station. However, with entirely similar turning motions, also vertical motions are carried out between display elements as they appear with selection of entries from long lists, for example during use of navigation systems or an address book. In one way, from this follows an inconsistent operating concept, since at first for the operator there results no clear relation between the identical motions of the operating element in the two instances, as well as the particular differing motion between the displayed contents or display elements appearing on the screen.

A turning motion of the operating element can cause on the screen both a horizontal and a vertical motion of a marking element between the display elements. The operator must initially actively make a reference or unambiguous connection between the turning motion or the operating element and the particular motion of the marking element occurring on the screen. If this connection is incorrectly made, the danger of a subsequent incorrect operation is great, which can lead to stress situations and frustration with possible further diminished attention to the surrounding traffic situation.

Multifunction operating devices are known in which a turnable roller is combined with numerous key elements, to navigate via the roller in menus organized vertically on a display, while, via selected key elements, a marking element is moved horizontally. It is true that in these systems, there exists in part a secure connection of individual key elements with the directions of movement of the marking element in a horizontal direction (DE000010139692A1, DE000010139693A1, and DE000010139694A1). However, in these systems, to navigate vertically using the turnable roller requires at least a glance at the screen on which the menus in question are shown. The arrangement of individual key elements is so selected with this that a glance at the particular operating element is required. Especially when the operating elements are positioned in an ergonomically advantageous position, such as in the vicinity of the armrest, the use of which is burdened with a disadvantage in that necessary glances to check the operating elements may cause with relatively long glances away from the traffic situation.

Even if it is not necessary to glance at the operating element, at least during operation of the systems previously described, the screen must be kept in view. A totally “blind” operation of the operating elements, thus operating without glancing away from the traffic situation, would be desirable, but does not appear to be attainable with these systems.

Display-supported technical systems are known in which a multi-functional operating element is integrated into the steering wheel of a motor vehicle (DE000019920525A1, DE000019941947A1, and U.S. Publication No. 2005/0021190A1). Currently, making up the operating element from individual key elements and rotating elements is comparable with traditional operating elements according to the state of the art, for which reason, allowance must generally be made in reference to disadvantages due to required glances at the screen. In addition, in such systems integrated into the steering wheel of vehicles there is possibly an overlap of the grasping motions required to grip the steering wheel, such as by finger motions for manipulation of the individual component part of the integrated operating element. At least in hectic driving situations, this entails the danger of possible incorrect operations.

An alternative concept for operation of multifunctional systems has been put into effect with integrated operating and display systems in the form of touch-sensitive screens, or so-called touch screens. Here the user can directly trigger the desired functions by touching a displayed operating element. Examples of use of such systems in motor vehicles are various systems in Ford, Volkswagen or Toyota vehicles, among others.

While it is true that a touch-sensitive screen does offer an advantage in that it is possible to depict operating and display elements integrated at one location. Deflections of the gaze to various locations in the vehicle's cockpit are thus avoided. Some disadvantages follow since more strict demands are placed fundamentally on the arrangement of a touch screen. For ergonomic reasons, the screen must be placed within the driver's reach, so that operation is easily accessible and at a minimum does not become less comfortable than would be the case with use of the already-described remote operating concepts. This would cause initially a rather lower positioning of the touch screen, for example in the area of the center console. True, with lower position of the screen, there is a longer deflection of the gaze to a position below the line of sight to driving conditions with lower positioning, which can lead to longer glances away from the driving situation. Thus, for example, the JAMA Guideline demands positioning of a screen in the center console in such an area that the center of screen is at most 30 degrees below the driver's visual plane. Placement for example at the end of an armrest or other ergonomic positions is practically precluded.

Every operationally-related glance away from traffic conditions that goes beyond a fleeting glance of an operating element or screen, leads to an additional problem, especially in older vehicle drivers. Time to accommodate the eyes viewing from distance to close-up vision, and vice versa, which increases with age, can lead to additional issues, since such accommodation time contributes to a prolonged effective removal of the gaze from the driving situation or, after the operating action, once again a prolonged accommodation time is required until the traffic situation can again be visually viewed with the requisite attention. This problem possibly intensifies with touch-sensitive screens, since the screen must be attached within the reach of the driver, resulting in a position relatively close to the driver.

Within the framework of certification-related limit conditions, compromise solutions thus frequently lead to the resulting installation location of touch-sensitive screens not in the ergonomically optimal location that would be required to acquire the information on the screen with as brief a glance as possible away from the driving situation, and at the same time make it possible to perform the desired operations and inputs comfortably and easily.

The task of the invention is to provide an operating element with whose aid even complex technical systems, especially display-supported technical systems in vehicles, can be operated safely, intuitively and advantageously in ergonomic terms, with the danger of incorrect operation largely precluded in a stress-endangered environment. With complete functionality, the operating element should offer configurationally options that ensure a high recognition value, and easy ergonomic use.

This problem is solved by an operating element with the features described below and in the claims. The dependent claims indicate advantageous embodiments of an invention-specific operating element.

### SUMMARY OF THE INVENTION

The invention consists of an operating element for technical systems in vehicles, comprising four separate operable key elements and a turnably supported roller that can be moved by pressure perpendicular to its axis of rotation, whereby the four key elements are arrayed in cross-like fashion and the turnably supported roller lies in the middle between the four key elements placed in cross-like fashion. The axis of rotation of the roller runs generally parallel to the plane in which the key elements are arrayed. The extension capacity of the roller is perpendicular to this plane; the roller can also be turned or pressed on by light finger pressure like a mechanical key and partially countersunk while doing so. Through this combination of key elements with a roller capable of being turned and countersunk into an invention-specific operating element there results a multifunctional operating element which is especially well adapted to the requirements for use in a vehicle, since especially in connection with display-supported technical systems as currently used in motor vehicles, a consistent operating and display concept is made possible, that is distinguished by comfort and safety.

Consideration is especially given that from an ergonomic viewpoint and for reasons of traffic safety, it is advantageous to place these displays as high as possible and in the immediate vicinity of the driver's field of vision in the normal position when using displays in vehicles, with the distance between display and driver being large enough that also while allowing for differing rates of accommodation, it is possible to switch between the required visual checks of the driving situation and the display. The display can be placed independent of the position of the operating element. Thus, the invention further makes possible a somewhat lower positioning of the manually operated operating element in comparison to the optimal display position. The invention-specific operating element can be within comfortable reach of the driver, while he assumes his normal posture chosen for driving the car. This is especially facilitated in that the arrangement and configuration of the operating element can be so selected that at least simple operating sequences can be run “blind,” with no need to deflect vision away from the driving situation during operation. This is an advantage relative to known remote operating concepts, which as a rule require glancing away from the driving situation during operation, both to the display and also to the operating element.

Advantageously the four separately operable key elements are arranged crosswise, so that two key elements, separated from each other by the turnably supported roller, lie horizontally next to each other and two key elements lie vertically over each other, also separated by the turnably supported roller. In this case, the key elements surround the centrally placed turnably supported roller, whereby, proceeding from the position of the roller, an alignment of the key elements results that makes possible an intuitive operation of the key elements for navigation on a screen. Especially, through a suitable configuration and assignment of the individual key elements, an unambiguous relation between operation of, and horizontal or vertical motion of a marking element on the screen can be realized. With this operating element, those disadvantages can be avoided that arise in part from a multiple assignment of customary operating elements during the navigation on the screen, when navigation or dialing up of individual display elements is undertaken via these four key elements. With this, what is understood as a marking element especially is also every form of identification of dialup or selection of a display element depicted on the screen.

In an advantageous fashion, the invention-specific operating element is so arranged that a hand rest is in its immediate vicinity. With this, the dimensioning can be so designed that the ball of an operator's hand remains resting during operation of an operating element. This results in a very safe operability, since the operator's hand absorbs virtually all disturbing accelerations, such as when passing over uneven road surfaces, via the secure contact to the hand rest, and carries out a forced motion and diminishes unintended movement in this regard. Disturbing relative motions between the operator's hand and the operating element, which could for example result in activation of a wrong key element, are thus largely avoided. The individual key elements, as well possibly as the turnably supported roller are operated in this case only by motion of the fingers with the hand otherwise resting.

Depending on the complexity of the expected operating sequences that are undertaken with the operating element, and the multiplicity of selectable depicted elements going hand-in-hand with that, that can be displayed in structured fashion for example in lists or so-called pop-up menus, it is appropriate to make the selection not via incremental steps through multiple pressings on the appropriate key element, but rather the desired dialup or placement of the marking element is accelerated by turning the turnably supported roller, which can also be designated as scrolling. With this, through corresponding alignment of the axis of rotation of the turnably supported roller, it is assured that the finger motion that turns the roller is likewise intuitively connected with the effected direction of motion of the marking element on the screen. Thus in advantageous fashion, for selecting a display element placed in a vertically structured list of display elements, the turning axis of the roller is aligned horizontally. One navigates on the screen in readily understood fashion in this case in a horizontal direction exclusively by pressing on the horizontally adjacent key elements; in contrast, in the vertical direction optionally either by pressing on the vertically adjacent key elements or by rotating the turnably supported roller in the center of the invention-specific operating element. One chooses the dialed display element, or activates the function connected with this display element always by pressing on the turnably supported roller, by which it moves perpendicular to its axis of rotation and triggers a switching procedure connected with this.

A further advantage of the invention-specific arrangement is the clear positional relations of key elements in relation to the turnably supported roller, which represents a superior and thus easily palpable structure, on which an operation can get oriented in “blind” fashion. If the operator feels the roller, the operator then will place his hand so that the already discussed mode of operation is possible with the ball of the hand resting and the fingers moving.

Depending on his degree of attentiveness and/or familiarity, the operator then will occasionally accompany manipulation of the operating element with a checking glance. To minimize visual diversions for checking glances at the operating element in this case as well, it can be advantageous to place the operating element in the upper part of the center console. This is especially true if this area is within easy manual reach. Then also, a hand rest in the immediate vicinity of the operating element is required, to minimize the influence of movements and vibrations of the vehicle on operation, since otherwise the operator's hand would be suspended freely in the air, i.e., in front of the center console. The function of the hand rest can be fulfilled advantageously by an area of the center console. Through this, when rough road sections are passed over, especially disturbing vertical motions of the arm and hand, and incorrect operations linked with that, are avoided.

An ergonomically advantageous arrangement of the invention-specific operating element the integration of the operating element into an outward-extended center console inclined relative to the vertical. It has been shown that through such an inclination of the center console by 20 degrees or 30 degrees, for example, the operation can be ergonomically optimized.

A further advantageous embodiment form of the invention, in connection with an appropriate position of the operating element, includes a hand rest that makes its possible to rest the hand of the driver and/or passenger in the direction of travel in front of the arm rest of the front seat during operation. This version makes particular sense if there is no gearshift lever between the hand rest and the operating element, as for example is the case if gears are shifted via a control stalk. Otherwise, the gearshift lever in the center console can also serve as a hand rest with certain prerequisites.

One further advantageous position for placement of the operating element is the front part of the arm rest. In this case, the arm rest itself serves as a hand rest and makes it possible for the operator to quickly and safely assume the correct hand position.

With the operating element presented, a very intuitive operating concept can be realized, which is sensed as quick and comfortable through the partial redundancy of the navigation options available for placement of a marking element. The key elements placed in the horizontal direction are used, to shift between display elements placed in a horizontal direction on a display, for example on the central information display, and thus to dial these up, by moving a marking element horizontally over the display. The key elements placed in a vertical direction are used to shift between display elements placed in a vertical direction on the display, and thus dial them up. Also included in this are displays in list form. Optionally, display elements through vertical motion of the marking element can also be dialed up by turning the roller, through which one can also shift between the display elements placed in a vertical direction on the display. Especially with long, list-configured groups of display elements, this can be perceived as desirable. Here, turning the roller makes it possible to run faster through the listed entries than by activating key elements causing incremental motions, for example in the form of switch-configured operating elements. A combination of the two options for dialing up vertically listed display elements has been shown to be especially operator-friendly, which combines the option of rapidly passing through long lists with the precision of a final dialup of a display element through few incremental steps. Thus, a marking element can be moved by rapid scrolling with the aid of the roller displaced in rotation into the vicinity of the display element ultimately dialed up, before precision selection is undertaken with the help of a few key movements.

Display elements dialed up by a confirmation or activation of a function connected with it are always selected by pressing on the turnably supported roller, regardless of whether the dialup was undertaken previously through turning the roller or operating the key elements.

Fundamentally, the invention-specific operating element includes mechanism for displaying status information available via the key elements, thus whether a key element has been activated or not. It further includes mechanism to display the turning angle of the turnably supported roller as well as information about extension of the roller perpendicular to its axis of rotation. Capable of serving as such media, which display the information named about the activation status of the invention-specific operating element, are fundamental technical mechanisms like switches, sensors and other devices, which are suitable to present the information needed in a form that can be evaluated. There must be a capability for evaluation as regards inclusion of this information into the corresponding display and operation concept and the software necessary to implement it.

Additionally, one advantageous embodiment of the invention includes additional media that make it possible to determine the duration for which a certain key element is pressed or felt. By this means, it is possible to implement multiple assignments of the individual key elements. With this, a brief pressing of the key in the manner already explained, serves to navigate on the display owing to two-dimensional motion of the marking element. Above a threshold value, through pressing longer on one of the key elements, one can shift sidewards on the display of listed entries in extensive lists, which is also designated as pagewise scrolling.

In a further advantageous embodiment of the invention, proximity sensors are included, that cause an operating element to light up automatically when a hand approaches. Especially for night driving, this additionally facilitates orientation in assuming the hand position necessary for operation, and reduces diversions of gaze that may be necessary. The illumination can be implemented in advantageous fashion with lighting up of individual components of the operating element or displays attached to it, especially in the form of text or icons.

All these embodiment forms can be used with advantage for configuring the passenger compartment of the vehicle. For example, it is possible to attain a better harmony in the configuration of the various operating elements in the vehicle cockpit. Added to this are new possibilities to make the center console incline relative to the vertical, to shape the console and naturally, to configure the operating elements integrated into the console, since through the invention-specific operating element, few structural limitations are created.

### BRIEF DESCRIPTION OF THE DRAWINGS

In what follows, the invention is explained with an embodiment example. Shown are:

FIG. 1 illustrates the arrangement of individual component parts of an invention-specific operating element;

FIG. 2 illustrates a simplified depiction of an invention-specific operating element in the form of a three-sided drawing;

FIG. 3 is a schematic depiction of an invention-specific operating element in the form of a touch-sensitive surface;

FIG. 4 is an excerpted schematic drawing of a center console with an invention-specific operating element; and

FIG. 5 is a schematic depiction of an arrangement of an invention-specific operating element in a motor vehicle.

### DETAILED DESCRIPTION OF THE PREFERRED EMBODIMENT

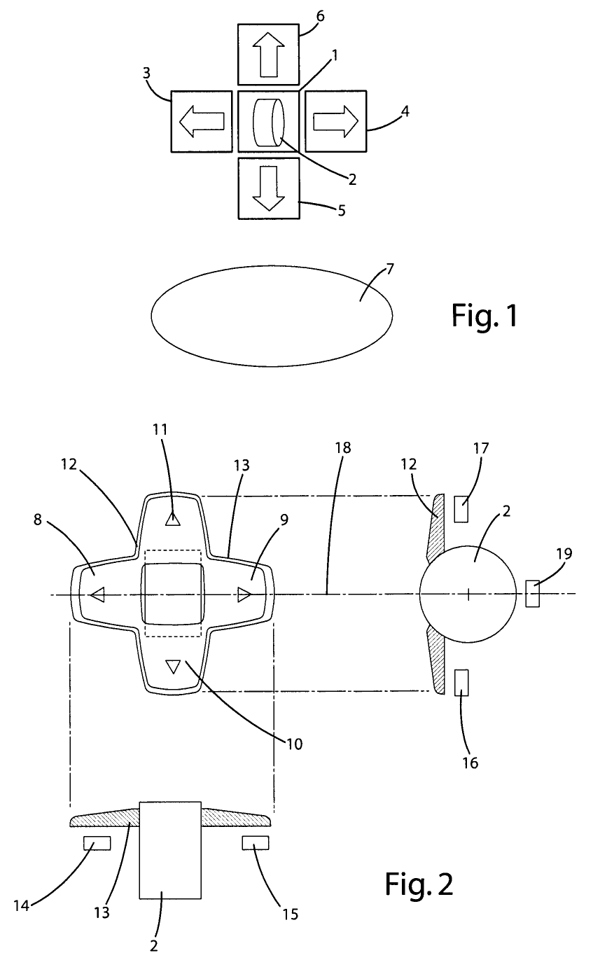

FIG. 1 shows the fundamental arrangement of individual component parts of an invention-specific operating element for clarification of the positional relations essential to the invention. This depiction is not of the specific configuration or style of the individual component parts, however their arrangement in the manner depicted is required to ensure that the operating element will be able to be operated in especially advantageous and safe fashion.

A central area 1 is provided for a turnably supported roller 2 that can be moved by pressing perpendicular to its axis of rotation that presently runs directed horizontally. This central area 1 for the turnably supported roller 2 is surrounded in star shape by four additional surface areas 3, 4, 5, 6 that each contain a key element. With these, any mechanism that can trigger an action by pressing and/or touching, that provide for a discrete navigation step of a marking element on a screen of a display-supported technical system are considered key elements. The star-shaped arrangement of surface areas 3, 4, 5, 6 in which the key elements are found, is so aligned that two key elements 3, 4 are horizontally next to each other and the two key elements 5, 6 are vertically one above the other. The connecting lines of the vertical and horizontal adjoining key elements intersect in area 1 of the turnably supported roller 2, that separates the adjoining key elements from each other. In this case, the key elements surround the centrally placed turnably supported roller 2, whereby based on the position of roller 2, an alignment of key elements results that makes possible an intuitive activation of key elements for navigation on a screen. Each key element is so tagged that its activation results in motion of the marking element necessary for navigation on the screen in the direction that is associated with the placement of each key element, viewed as based on the position of turnably supported roller 2. This directional association results as indicated by the arrows in surface areas 3, 4, 5, 6 provided for the key elements. Thus, there is an unambiguous connection of individual key elements with the horizontal or vertical motion of the marking element on the screen.

The extension of individual surface areas 1, 3, 4, 5, 6 as well as the intervals between them are so chosen that they can be reached by simple finger motions, while the ball of an operating hand can remain supported. A hand rest is provided for resting the ball of the hand, which is found in an additional surface area 7.

The advantage of such an arrangement of individual component parts of the invention-specific operating element is especially the small expense to implement a consistent operating and display concept. Thus, high operating safety can be combined with easy operability that requires little attentiveness owing to its intuitive character, and can be implemented in appropriate operating and display concepts in optimal fashion. A further advantage lies in easy adaptability to various display-supported technical systems, if their software design corresponds with the fundamental usual components of selection and dialup steps and the vertical and horizontal grouping of display elements.

Such an operating and display concept can be advantageously implemented if the above-described arrangement of component parts of the operating element is accommodated at a location that is ergonomically favorable for the driver and if necessary also for the passenger, preferably in the area of the center console. In addition, this would have an advantage in that fundamentally proven and cost-optimized architectures of the center console could be maintained, and only need to be slightly modified. This represents a considerable cost advantage for introduction of the invention-specific operating element.

It has been shown to be advantageous for the operating concept with a resting ball of the hand if the area in which the surface areas 1, 3, 4, 5, 6 for the key elements and the turnably supported roller 2 is found, overall has an area of 5 cm×5 cm to 8 cm×8 cm. For similar reasons, it has been shown to be advantageous if turnably supported roller 2 has a diameter of 2 cm to 5 cm.

FIG. 2 shows a simplified illustration of an invention-specific operating element in the form of a three-sided depiction. Measurements felt to be advantageous are to be gleaned from the side view. The key elements 8, 9, 10, 11 are attached in the form of two crossed rockers, 12, 13, behind whose ends separate switching elements 14, 15, 16, 17 are placed, that react to extensions of rockers 12, 14 caused by pressure. The ends of the rockers thus form the key elements in accordance with the invention. Despite only two rockers 12, 13, the embodiment form depicted includes an arrangement made up of four key elements 8, 9, 10, 11 that are included into the operating element in the form of key switches, thus electromechanical assemblies, and are separately pressure-operated. In the center of the arrangement is a turnably supported roller 2, that projects through an opening in rockers 12, 13 and thus can be directly manipulated. The axis of rotation 18 runs in a horizontal direction parallel to the main extension plane of rockers 12, 13. When an appropriate pressure is exerted, roller 2 is moved perpendicular to its axis of rotation 18, whereby the roller activates a switch 19 that is in a covered location, via which this movement of roller 2 can be detected. Through the depicted alignment of rockers 12, 13 an operating element results in which four separately operable key elements 8, 9, 10, 11 are so arranged crosswise, that two key elements 8, 9 are next to each other horizontally and two key elements 10, 11 lie vertically one atop the other, which promotes the intuitive operability already addressed.

It becomes evident from the embodiment form depicted that if the positional relation shown in FIG. 1 between the individual components of the operating element is maintained, an extraordinarily large configurationally leeway results without needing to deviate from the invention-specific operating concept. From this there follows at least an option to use the operating element to conceive, configure and implement a brand-typical operating and display concept, for example through the depicted striking design in the form of a cross.

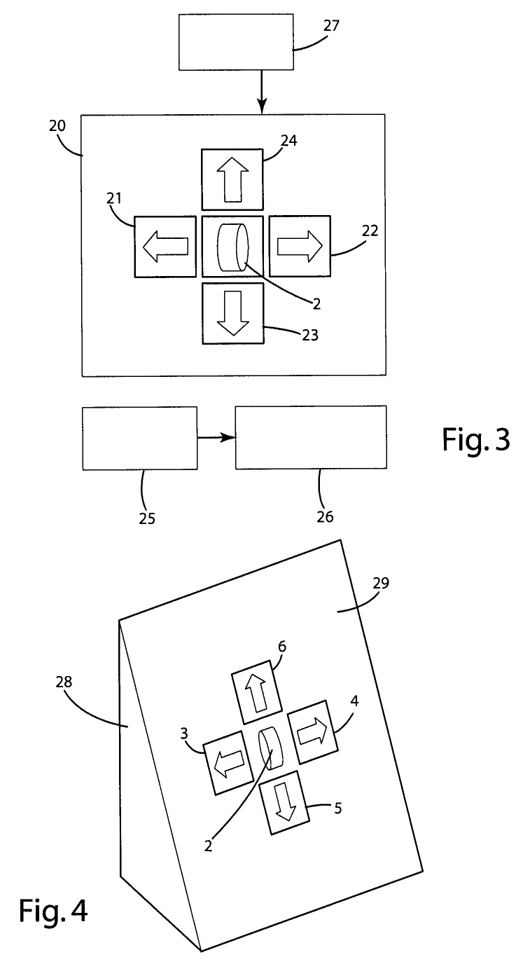

FIG. 3 illustrates an alternate to the completely electromechanically designed version, the invention-specific operating element can be integrated into a touch-sensitive surface 20. Then what serves as key elements are surface areas 21, 22, 23, 24 to be appropriately queried, as per the arrangement from FIG. 1, in which touching is detected as an operating action. This embodiment form with a touch-sensitive surface can in turn advantageously be equipped with proximity sensors 25, that for example are used for activation of integrated lighting with suitable lighting elements 26, that make possible illumination or backlighting of the components of the operating element, before the surface itself is touched.

In advantageous fashion, when the touch-sensitive surface 20 or surface areas 2, 21, 22, 23, 24 or operating elements are touched, vibration of these surfaces is triggered, that evokes in the user an impression of an activation similar to the activation of a classic mechanical operating element. For this it is advantageous if actuators 27 are included, that provide with activation of one of the key elements, the touch-sensitive surface 20 and or the key elements 2, 21, 22, 23, 24 are moved perpendicular to their plane. The haptic impression connected with this simultaneously conveys a confirmation of successfully completed operational actions.

FIG. 4 shows an excerpted schematic depiction of a center console 28 with an invention-specific operating element. On one surface 29 for accommodation of operating elements, the individual components 2, 3, 4, 5, 6 of the operating element, already explained in detail, are placed. On the operator side, this surface 29 forms the end of the center console 28. The surface 29 for accommodating operating elements is inclined by about 30° to the vertical. In accordance with the invention, this means that the operating element is integrated into a center console that is inclined 20°-30° to the vertical, although presently it depends only on the inclination of surface 29 relevant for the operation. This inclination facilitates a relaxed resting of the hand, which in turn accords with intuitive or automated operation of the operating element as is customary.

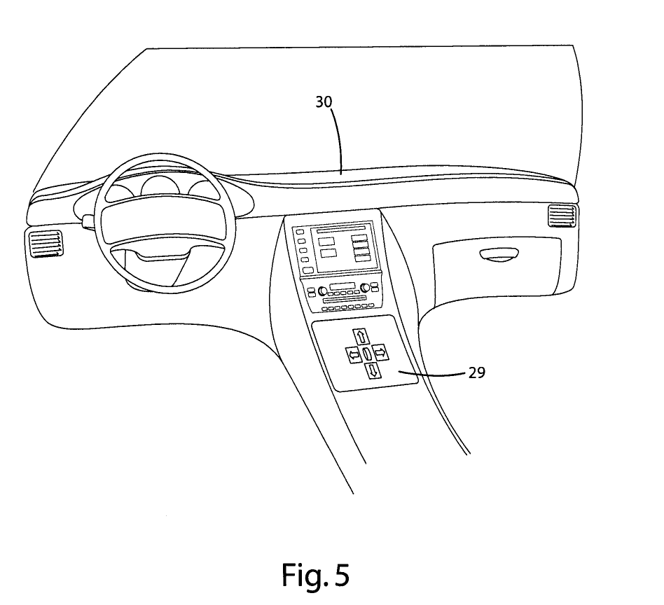

FIG. 5 shows a schematic depiction of the arrangement of an invention-specific operating element in a motor vehicle. It illustrates an advantageous positional relation for operation. With this, a conventionally configured vehicle cockpit forms the point of departure, which is depicted by known paneling elements 30. One surface 29 for accommodation of operating elements, thus preferably of an invention-specific operating element, is found in a position pushed out in the direction of the driver. This can, for example, be implemented by a center console inclined and/or pulled out according to FIG. 4. What is decisive is that the operating element, depicted through its individual components 2, 3, 4, 5, 6 is moved into the manual range of the driver, to be able to use its advantageous operability to the full extent.

A display-supported technical system that is served by an operating element according to an invention-specific embodiment, demands a differing degree of attentiveness while being operated, depending on the degree of complexity of the operating action and depending on experience, which can be explained roughly by assignment to three degrees of difficulty.

Substantial navigation on the display, for example using multiple menu levels and paging through extensive lists with numerous display elements, as a rule demands longer deflection of the gaze to the screen, or at least frequent glances to check the screen. In the get-accustomed phase, in addition, at times it is necessary to divert the gaze to the operating element.

However, ergonomic configuring of the operating element does permit one, even after a short get-accustomed phase, to dispense almost entirely with glances to check the operating element. But complex operating actions, especially when the turnably supported roller is used, nonetheless require a more lengthy diversion of the gaze to the screen or at least frequent glances to check the screen.

After a few repetitions during the get-acquainted phase, shorter operating actions that require only a few navigation steps to dial up a desired display element, can be carried out in many cases “blind” via a brief pressure on the turnably supported roller, including selection or activation of the dialed-up functionality, and thus require neither a deflection of the gaze to the screen nor a deflection of the gaze to the invention-specific operating element, if the operator can undertake the operating action from memory.

It is up to the developers of the software used, that as many and frequently recurring operating actions are organized so that they are linked to as few navigation steps as possible, especially if we are dealing with typical operating actions that occur as a rule while driving an appropriately equipped vehicle. This can for example be implemented by arranging the display elements to be selected during these operation actions to be relatively closely adjoining, to make it unnecessary to do “scrolling” in long lists with these operating actions. A “blind” operation as a rule will presuppose that the turnably supported roller is only used as a fifth key element for selection or activation of a display element, which previously has been dialed up via a navigation only with the four key elements through incremental steps. The redundancy in assignment of the individual components of the operating element, which makes possible their optional use for dialing up a display element, is an important prerequisite for the arrangement of operating algorithms that are suitable for a “blind” operation, without having to dispense during more complex operating actions with the operating comfort that is now customary.

Being able to totally do away with gazes deflected to the operating element after the get-acquainted phase in connection with a remote operation concept makes it possible to display the necessary information in the upper area of the center console, thus allowing, in the concept of a screen that is as close as possible in the driver's visual focus and that is proven and minimizes driver distraction, a determination of what is connected with minimal head movements and changes in direction of gaze.

The intuitive nature of operating a technical system via the invention-specific operating element facilitates configuring a display concept that, in combination with a central information screen, makes possible ergonomically optimal operation. Especially the unambiguous relation between operation of each key element and each marking element motion thus effected, horizontally or vertically on the screen, in precisely the direction that is intuitively connected with the particular key element, comes close to the “what-you-see-is-what-you-get” principle known from software ergonomics, which is viewed in various applications as especially user-friendly and can be implemented on the present operating element in an improved, vehicle-specific form.

The foregoing discussion discloses and describes an exemplary embodiment of the present invention. One skilled in the art will readily recognize from such discussion, and from the accompanying drawings and claims that various changes, modifications and variations can be made therein without departing from the true spirit and fair scope of the invention as defined by the following claims.

What is claimed is:

1. The operating element for technical systems in vehicles, comprising four separate operable key elements and a turnably supported roller that can be moved by pressure perpendicular to its axis of rotation, characterized in that the four key elements are placed crosswise and the turnably supported roller is in the center between the crosswise-arranged key elements, whereby the axis of rotation runs parallel to the plane of the key elements and the movability of the roller is perpendicular to this plane.

2. The operating element of claim 1, characterized in that the four separately operable key elements are arranged crosswise so that two key elements are horizontally next to each other and two key elements are vertically one atop the other.

3. The operating element of claim 1, characterized in that the key elements are so arranged that they are moved out when operated by the operator's finger pressure.

4. The operating element of claim 3, characterized in that each two of the key elements are integrated into a rocker.

5. The operating element of claim 2, characterized in that the key elements are arranged as surface areas of a touch-sensitive surface.

6. The operating element of claim 5, characterized in that actuators are included, that ensure that when one of the key elements is operated, the touch-sensitive surface is moved perpendicular to its plane.

7. The operating element of claim 1, characterized in that proximity sensors and lighting elements are included, which are so arrayed, that when an operator's hand approaches, at least parts of the operating element automatically light up.

8. The operating element of claim 1, characterized in that the operating element is placed next to a hand rest in such a way that all components of the operating element can be operated by finger movements with the ball of the hand supported.

9. The operating element of claim 1, characterized in that the operating element is integrated into the center console of a vehicle.

10. The operating element of claim 1, characterized in that the operating element is integrated into a center console that is inclined by 20°-30° to the perpendicular.

11. The operating element of claim 9, characterized in that the center console is a pulled-out center console that is within the driver's reach in the area of the operating element, if while driving he has assumed his normal position.

12. The operating element of claim 1, characterized in that the operating element is integrated into the front part of an arm rest.

13. The operating element of claim 1, characterized in that the area in which the surface areas for the key elements and the turnably supported roller are found, overall has a dimension of 5 cm×5 cm to 8 cm×8 cm.

14. The operating element of claim 13, characterized in that the turnably supported roller has a diameter from 2 cm to 5 cm.

15. The operating element of claim 1, characterized in that the key elements are so assigned that a brief pressing on one of the key elements causes a navigation motion of a marking element on a screen in a direction firmly connected with the pressed key element, by a discrete step.

16. The operating element of claim 15, characterized in that the navigation direction firmly connected with the pressed key element corresponds to the direction in which the pressed key element is arranged, viewed from the position of the turnably supported roller.

17. The operating element of claim 1, characterized in that the key elements are so assigned that when pressed for a longer time, at least one of the key elements makes available a second function of this key element.

18. The operating element of claim 17, characterized in that at least one key element is so assigned that when pressed for a longer time, it causes a sideways paging in display elements that can be shown on a screen.

19. The operating element of claim 1, characterized in that the turnably supported roller is so assigned that a rotation of the roller causes motion of a marking element along a row of display elements on a screen.

20. The operating element of claim 19, characterized in that the row of display elements on a screen is a vertically organized list of display elements.

21. The operating element of claim 20, characterized in that the turnably supported roller is so assigned that a brief pressing on the roller confirms the selection of an already dialed-up display element on a screen and/or activates a function connected with the display element.
